(19) United States
(12) Patent Application Publication
(10) Pub. No.: US 2024/0345484 A1
(43) Pub. Date: Oct. 17, 2024

(54) PROCESSING SYSTEM, AND PROCESSING METHOD

(71) Applicant: Tokyo Electron Limited, Tokyo (JP)

(72) Inventor: Shinji Kobayashi, Koshi City (JP)

(21) Appl. No.: 18/632,672

(22) Filed: Apr. 11, 2024

(30) Foreign Application Priority Data
Apr. 12, 2023 (JP) 2023-064749

(51) Int. Cl. G03F 7/30; B01D 61/02; B01D 61/14; B01D 65/02; C02F 1/04; C02F 1/44; C02F 1/72; C02F 103/34

(52) U.S. Cl. CPC G03F 7/3092; B01D 61/025; B01D 61/145; B01D 65/02; C02F 1/04; C02F 1/441; C02F 1/444; C02F 1/72; B01D 2313/083; B01D 2321/04; C02F 2103/346; C02F 2301/043; C02F 2303/16

(57) ABSTRACT

A PFAS detoxification system 1 includes a concentrating device 11 configured to concentrate a resist waste liquid containing PFAS discharged from a lithography apparatus 111 of a semiconductor manufacturing apparatus 100. Further, the PFAS detoxification system 1 includes a sulfuric acid processing tub 12 configured to decompose and volatilize a concentrate concentrated by the concentrating device 11.

### CROSS-REFERENCE TO RELATED APPLICATION

This application claims the benefit of Japanese Patent Application No. 2023-064749 filed on Apr. 12, 2023, the entire disclosure of which is incorporated herein by reference.

### TECHNICAL FIELD

The various aspects and embodiments described herein pertain generally to a processing system and a processing method.

### BACKGROUND

Patent Document 1 describes a wastewater processing system including a processing apparatus for reducing a content ratio of an organic fluorine compound or the like; an anion exchange tower filled with an ion exchanger containing an anion exchanger; and a decomposing apparatus configured to decompose a recycled liquid flown to the anion exchange tower.

Patent Document 1: Japanese Patent Laid-open Publication No. 2010-125352

### SUMMARY

In one exemplary embodiment, a processing system includes a developing liquid concentrator configured to concentrate a waste liquid containing a positive developing liquid, discharged from a semiconductor manufacturing apparatus; and a chemical liquid processor configured to decompose and volatilize a first concentrate concentrated by the developing liquid concentrator.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic diagram of a PFAS detoxification system according to an exemplary embodiment;

FIG. 2 is a configuration diagram of the PFAS detoxification system shown in FIG. 1;

FIG. 3 is a diagram for describing filtration of a liquid containing PFAS;

FIG. 4 is a diagram for describing cleaning of a filter through a backflow of a filtrate;

FIG. 5 is a diagram for describing separation of a gas;

FIG. 6 is a diagram for describing a function of a gas filter;

FIG. 7 is a diagram for describing separation of exterior air which has been taken in;

FIG. 8 is a diagram for describing concentration and decomposition of a positive developing liquid;

FIG. 9 is a diagram for describing cleaning of a filter through a backflow of a filtrate;

FIG. 10 is a diagram for describing a discharge of a SPM waste liquid;

FIG. 11 is a diagram for describing cleaning of a filter by the SPM waste liquid;

FIG. 12 is a diagram for describing a decomposition processing chamber according to a modification example; and

FIG. 13 is a diagram for describing a return line according to the modification example.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments will be described with reference to the accompanying drawings. In the following description, same parts or parts having same functions will be assigned same reference numerals, and redundant description thereof will be omitted.

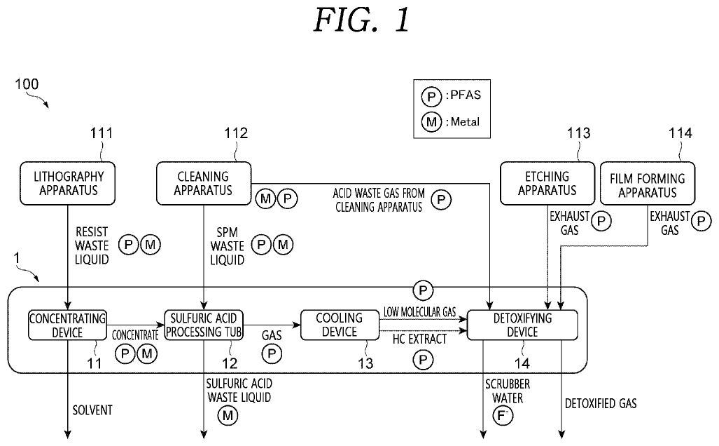

A processing system according to an exemplary embodiment is a PFAS detoxification system 1 configured to detoxify PFAS discharged from a semiconductor manufacturing apparatus 100, as shown in FIG. 1. A schematic configuration of the PFAS detoxification system 1 is shown in FIG. 1, and illustration of some components (for example, components related to a TMAH (tetramethyl ammonium hydroxide) waste liquid to be described later) is omitted. Here, PFAS refers to Per-and Poly-FluoroAlkyl Substance, which is an organic fluorine compound.

PFAS is a compound containing at least one aliphatic molecular of —CF2- or —CF3, and also contains an organic high molecular compound (polymer) such as Teflon. PFAS is contained in, for example, a foam fire extinguishing agent, a plating liquid, aircraft hydraulic oil, a water repellent, floor wax, and so forth. Also, PFAS is contained in, for example, textiles, medical products, electronic boards, automobiles, food packaging, stone, flooring, leather, and so forth. In a semiconductor manufacturing process, non-polymer PFAS is used as a photoresist, for example. In addition, polymer PFAS is used in antireflection films, liquid-contact members such as pipelines, valves, and pumps, and so forth in a semiconductor manufacturing apparatus.

PFAS is stable in nature and is difficult to decompose. For this reason, PFAS is highly persistent, tends to be easily accumulated in a living body, and is said to be highly harmful. The PFAS detoxification system 1 according to the present exemplary embodiment is configured to detoxify the PFAS discharged from the semiconductor manufacturing apparatus 100, thus suppressing the PFAS from being discharged to the outside.

As shown in FIG. 1, the PFAS detoxification system 1 includes a concentrating device 11 (a concentrator, a waste liquid storage), a sulfuric acid processing tub 12 (a chemical liquid processor, a decomposition processor), a cooling device 13 (collector), and a detoxifying device 14 (combustion detoxifying device). Further, in the present exemplary embodiment, although the PFAS detoxification system 1 is described as being a device group including a plurality of devices, the PFAS detoxification system 1 may be comprised of one device. Further, the semiconductor manufacturing apparatus 100 includes a lithography apparatus 111, a cleaning apparatus 112, an etching apparatus 113, and a film forming apparatus 114. Each component of the semiconductor manufacturing apparatus 100 discharges a substance containing PFAS when they perform processings. In addition, the individual processors constituting the PFAS detoxification system 1 may or may not be provided in the same space (place). For example, each processor may be installed within a building where the lithography apparatus 111, the cleaning apparatus 112, or the etching apparatus 113 is provided, or may be provided outside or adjacent to the building. Alternatively, the individual processors may be provided inside and outside the building separately. Furthermore, among the concentrating device 11, the sulfuric acid processing tub 12, the cooling device 13, and the detoxifying device 14, the one(s) not in use need not be provided at all times.

The lithography apparatus 111 includes a coating/developing apparatus and an exposure apparatus. The exposure apparatus performs an exposure processing for a resist film. Specifically, an energy ray is radiated to an exposure target portion of the resist film (photosensitive film) by such a method as liquid immersion exposure. The coating/developing apparatus performs a processing of forming the resist film on a surface of a substrate prior to the exposure processing by the exposure apparatus, and performs a developing processing for the resist film after being subjected to the exposure processing. A liquid or a gas discharged from this lithography apparatus 111 contains PFAS. For example, the PFAS is contained in a resist waste liquid, an alkaline waste liquid (positive developing liquid) resulting from the developing processing, an acid waste liquid resulting from resist peeling, an organic exhaust, a thermal exhaust, a solidified sublimate, and so forth. In addition, an organic solvent waste liquid resulting from a negative development processing can also regarded as a very light resist waste liquid, contains PFAS, and may be treated in the same manner as the aforementioned resist waste liquid in the present exemplary embodiment. In the present exemplary embodiment, the PFAS contained in the resist waste liquid and the PFAS contained in the positive developing liquid will be mainly explained. The PFAS contained in the resist waste liquid may be, by way of non-limiting example, a photo acid generator (PAG), a surfactant, a F-modified polymer, and so forth. The resist waste liquid discharged from the lithography apparatus 111 is introduced into the concentrating device 11 of the PFAS detoxification system 1.

The cleaning apparatus 112 performs a cleaning processing on the substrate. For example, the cleaning apparatus 112 uses SPM (Sulfuric acid hydrogen Peroxide Mixture), which is a mixture of H₂O₂ and sulfuric acid, to remove an organic substance such as resist. The cleaning apparatus 112 uses a mixed aqueous solution SC2 (Standard Clean 2), which is a mixture of H₂O₂ and hydrochloric acid to remove a metal, and uses a mixed aqueous solution SC1, which is a mixture of H₂O₂ and ammonia, to remove a particle. Further, only hot concentrated sulfuric acid may be discharged during a waste liquid processing. The cleaning apparatus 112 discharges a SPM waste liquid containing PFAS. The SPM waste liquid and the hot concentrated sulfuric acid discharged from the cleaning apparatus 112 are introduced into the sulfuric acid processing tub 12. Furthermore, the cleaning apparatus 112 discharges an acid waste gas containing PFAS. The acid waste gas discharged from the cleaning apparatus 112 is introduced into the detoxifying device 14.

The etching apparatus 113 performs an etching processing to etch an oxide film and a thin film according to the pattern of the formed resist film. The etching apparatus 113 discharges an exhaust gas containing PFAS. The exhaust gas discharged from the etching apparatus 113 is introduced into the detoxifying device 14.

The film forming apparatus 114 forms a wiring film and an insulating film on the substrate. The film forming apparatus 114 uses various kinds of processing gases (gases containing or not containing PFAS), and discharges an exhaust gas therefrom. The exhaust gas discharged from the film forming apparatus 114 is introduced into the detoxifying device 14.

The concentrating device 11 concentrates the resist waste liquid containing the PFAS discharged from the lithography apparatus 111 of the semiconductor manufacturing apparatus 100. That is, the concentrating device 11 concentrates a substrate processing waste liquid in the lithography apparatus 111 as a waste liquid containing PFAS. The concentrating device 11 concentrates the resist waste liquid by using, for example, a ultrafiltration membrane or a reverse osmosis membrane, and, also, separates a solvent contained in the resist waste liquid (details will be described later). Since the concentrate of the resist waste liquid is a concentrate containing polymer, its viscosity is high. The concentrate of the resist waste liquid is introduced into the sulfuric acid processing tub 12. Furthermore, when the alkaline waste liquid discharged from the lithography apparatus 111 is concentrated by the concentrating device 11, the alkaline waste liquid may be introduced into the reverse osmosis membrane after being neutralized.

The solvent separated from the resist waste liquid may be used as a recycled solvent for cup cleaning or the like in the semiconductor manufacturing apparatus 100, or may be collected by a solvent recovery company. Conventionally, when the solvent recovery company performs component analysis in an attempt to purify the recycled solvent from the resist waste liquid, there is a risk that the waste liquid containing a confidential substance of a resist manufacturer may also be collected. In this regard, since the resist waste liquid that has passed through the concentrating device 11 as in the present exemplary embodiment contains a solid component in the concentrate, leakage of confidential information to the solvent recovery company can be suppressed.

The sulfuric acid processing tub 12 decomposes and volatilizes the concentrate concentrated by the concentrating device 11 with the SPM waste liquid. That is, the sulfuric acid processing tub 12 uses the SPM waste liquid from the cleaning apparatus 112. In the SPM waste liquid, a solvent and a polymer undergo a decomposition reaction of a dehydration reaction or an oxidation reaction, resulting in low molecular weight (low viscosity). At this time, the temperature of the SPM waste liquid increases due to an exothermic reaction (specifically, the temperature of the hot concentrated sulfuric acid in the SPM waste liquid increases). Although PFAS is not basically decomposed, a component such as PAG has low boiling point to be evaporated by the SPM waste liquid of the high temperature (in particular, the component such as PAG volatilizes by the effect of the hot concentrated sulfuric acid contained in the SPM waste liquid). Conventionally, a waste liquid processing for the SPM waste liquid is performed by adding catalase to suppress foaming. If, however, the SPM waste liquid is made to react with an organic matter in the sulfuric acid processing tub 12 and is thus degassed as a result of using up the H₂O₂ component, a sulfuric acid waste liquid on the downstream side does not foam and can be processed easily. Further, the amount of the catalase used can be reduced. Since this reaction accompanies generation of heat of, e.g., about 300° C., thermal energy conversion using waste heat or steam power generation using steam generated from circulating water for cooling the sulfuric acid processing tub 12 may be performed. Furthermore, the sulfuric acid waste liquid discharged from the sulfuric acid processing tub 12 is collected by, for example, a recycling company. This sulfuric acid waste liquid may have higher purity of sulfuric acid than the conventional waste liquid. In addition, in order to suppress unexpected ignition, it is desirable to carry out this processing in the sulfuric acid processing tub 12 in an atmosphere of a nitrogen gas which is an inert gas. Moreover, the SPM waste liquid may be a hot concentrated sulfuric acid waste liquid. In this case, the solvent and the polymer undergo a decomposition reaction of a dehydration reaction, resulting in low molecular weight (lower viscosity). At this time, the temperature of the hot concentrated sulfuric acid increases due to an exothermic reaction, causing the PFAS, the PAG, and the like to volatilize.

When the processing is carried on by adding the concentrate of the resist waste liquid to the SPM waste liquid stored in the sulfuric acid processing tub 12, H₂O₂ is gradually consumed, so that a processing capacity decreases. After supplying an appropriate amount of the concentrate of the resist waste liquid, the sulfuric acid processing tub 12 is put on standby until the reaction subsides and generation of the gas is completed. Since the SPM waste liquid from the cleaning apparatus 112 is of a large quantity, it is necessary to process the SPM waste liquid from the cleaning apparatus 112 without a delay. To this end, the sulfuric acid processing tub 12 may be composed of a plurality of processing tubs. In this case, while one processing tub is processing, preparation such as supply of a liquid may be performed in another processing tub. Further, by observing the progress of the reaction, the liquid may be flown downstream, such as in the order of a first processing tub, a second processing tub, and then a third processing tub. In addition, when the resist waste liquid is a metal-containing resist, only a metal component precipitates without volatilizing and is processed together with the sulfuric acid waste liquid in the same processes as described above.

Since the SPM waste liquid contains hydrogen peroxide, if it is discharged without being processed, it may foam and put a burden on the apparatus, or may deteriorate the environment as a foaming gas. In the configuration according to the present exemplary embodiment, however, since the remaining hydrogen peroxide is effectively utilized and the foaming gas is burned as fuel in the detoxifying apparatus 14, the burden on the apparatus and the environment can be reduced.

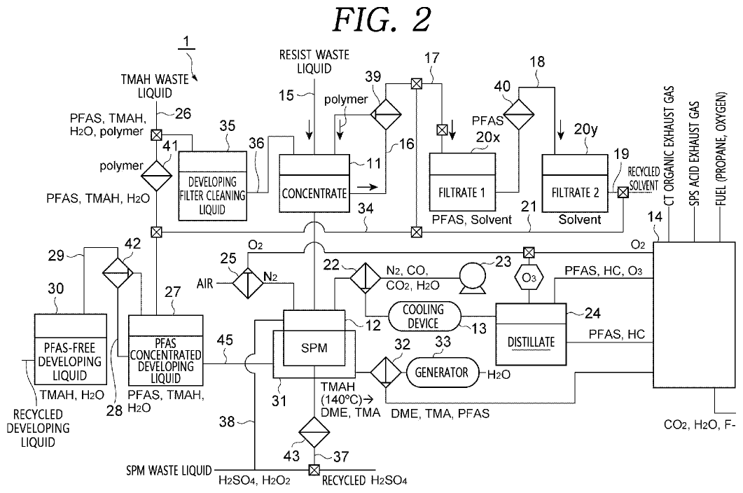

The cooling device 13 collects the PFAS-containing gas volatilized by the sulfuric acid processing tub 12 by liquefying it. The cooling device 13 collects the gas while separating the gas into a low molecular gas, which is a gas component, and a hydrocarbon (HC) extract, which is a liquid component. As illustrated in FIG. 2, as the gas from the sulfuric acid processing tub 12 is cooled in the cooling device 13, the liquefied gas is collected as the HC extract, and the low molecular gas that has not been condensed is also collected. Since the gas generated from the sulfuric acid processing tub 12 is processed in the nitrogen atmosphere, it is mixed with nitrogen. For the mixed gas containing a large amount of nitrogen, a processing amount in the subsequent detoxifying device 14 is large, so the low molecular gas that has not been condensed in the cooling device 13 may be concentrated while being separated into nitrogen and others by using a nano sub-ceramic filter, for example.

Various kinds of organic gases and other gases are discharged from the sulfuric acid processing tub 12 described above. PFAS such as PAG is also discharged as a gas. It may be considered to introduce these gases directly into the detoxifying device 14. In case of a gas which becomes a liquid at a room temperature, however, by once liquefying this gas in the cooling device 13, transportability thereof can be improved. Further, when transporting this gas without liquefying it, a liquid puddle may be formed in a portion of a pipeline, which is difficult to control. Both the liquefied HC extract and the non-condensed low molecular gas contain PFAS. The HC extract and the low molecular gas are introduced into the detoxifying device 14. Additionally, in order to further improve the transportability of the gases, all the gases, including the low molecular gas, may be introduced into the detoxifying device after being liquefied.

The detoxifying device 14 detoxifies the substances after being processed by the cooling device 13. The detoxifying device 14 may be a combustion detoxifying device that detoxifies the substances after being processed in the cooling device 13 by combustion. The detoxifying device 14 incinerates the HC extract and the low molecular gas introduced from the cooling device 13. Since most of the HC extract is hydrocarbon, it can be burned as fuel. In addition, since most of the low molecular gas is hydrocarbon having 10 or less carbon atoms, it can also be burned as fuel. Conventionally, a propane gas or a city gas has been used as fuel in a combustion detoxifying device. Since, however, the HC extract is used as fuel as stated above, the consumption amount of the propane gas, or the like can be reduced.

In addition, the detoxifying device 14 may simultaneously detoxify the exhaust gas introduced from the etching apparatus 113, the exhaust gas introduced from the film forming apparatus 114, and the acid waste gas introduced from the cleaning apparatus 112 by combustion. These gases are exhaust gases containing PFAS used in the respective apparatuses. By burning and detoxifying these gases simultaneously, the consumption amount of the propane gas or the like can be further reduced. Additionally, during the combustion detoxification, electric power may be generated by combustion using an internal combustion engine such as a gas turbine. A detoxified gas such as carbon dioxide may be collected to be used to synthesize an organic substance such as methanol or formic acid. In addition, the detoxifying device 14 may be a subcritical processing device configured to perform a subcritical processing on the substance after being processed by the cooling device 13, or a supercritical processing device configured to perform a supercritical processing thereon. Furthermore, the detoxified waste gas may be processed into F ion-containing scrubber water and a waste gas through a scrubber device (a device configured to wash the exhaust gas with water, neutralize the washed exhaust gas with a chemical liquid, or adsorb the exhaust gas to discharge it into the atmosphere). The scrubber water can be converted into calcium fluoride or fluorite by being made to react with calcium. The fluorite is a starting material for a fluorine compound, and can be recycled as a resource.

Now, details of the PFAS detoxification system 1 shown in FIG. 1 will be described with reference to FIG. 2 to FIG. 11. FIG. 2 presents a configuration view of the PFAS detoxification system 1 shown in FIG. 1. In FIG. 2, the components (the components related to a TMAH waste liquid, etc.) not shown in FIG. 1 are also illustrated. The PFAS detoxification system 1 includes a waste liquid supply path 15 (second supply path), a circulation path 16 (first path), a first filtrate path 17 (second path), a second filtrate path 18 (fourth path), a third filtrate path 19 (third path), a first storage 20x, and a second storage 20y. The PFAS detoxification system 1 further includes a bypass path 21. The PFAS detoxification system 1 is also equipped with a first gas filter 22, a vacuum pump 23, and a distiller 24. The PFAS detoxification system 1 is further equipped with a second gas filter 25. The PFAS detoxification system 1 further includes a waste liquid supply path 26 (first supply path), a concentrating device 27 (developing liquid concentrator), a circulation path 28, a developing liquid path 29, a recycled developing liquid storage 30, a developing liquid processing tub 31 (chemical liquid processor), a third gas filter 32, and a generator 33. The PFAS detoxification system 1 further includes a bypass path 34, a backflow liquid storage 35, and a recovery path 36. The PFAS detoxification system 1 also includes a discharge path 37. The PFAS detoxification system 1 is further equipped with an SPM supply path 38.

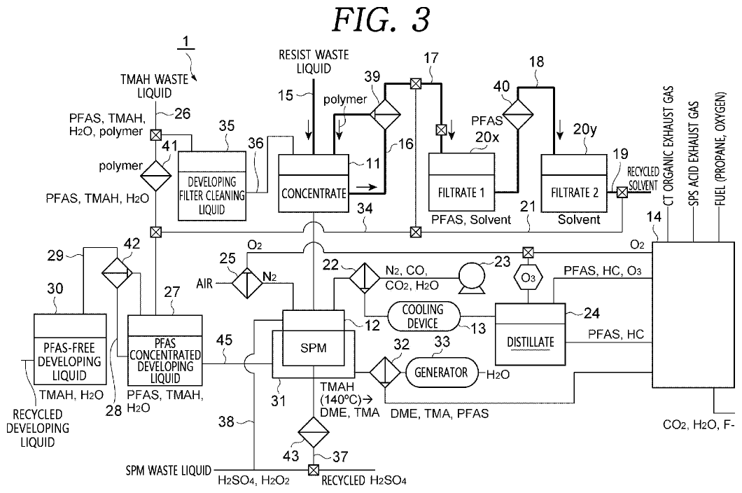

FIG. 3 is a diagram for describing filtration of the resist waste liquid, which is a liquid containing PFAS. As described above, the concentrating device 11 concentrates the resist waste liquid containing PFAS discharged from the lithography apparatus 111. The circulation path 16 is connected to the concentrating device 11, and a filter 39 (first filter) is provided at a portion of this path to exclude a polymer. The filter 39 is, for example, a hollow fiber filter. By providing the filter 39, the resist waste liquid is concentrated. A filtrate (solvent) that has passed through the filter 39 flows through the first filtrate path 17 and is stored in the first storage 20x (filtrate storage). This filtrate is a PFAS solution having a low concentration. The first storage 20x is a storage that is connected to the first filtrate path 17, and stores therein the filtrate. The second filtrate path 18 (filtrate storage) is a flow path connecting the first storage 20x and the second storage 20y. The second filtrate path 18 is provided with a filter 40 (second filter). The filter 40 is, for example, an ion exchange resin filter. By providing the filter 40, the filtrate that has passed through the filter 40 can be made into a solution that does not contain PFAS. The filtrate that has passed through the filter 40 flows through the second filtrate path 18 to be stored in the second storage 20y. This filtrate can be used as a recycled solvent, and flows to the outside from the third filtrate path 19, which is a position downstream of the second storage 20y.

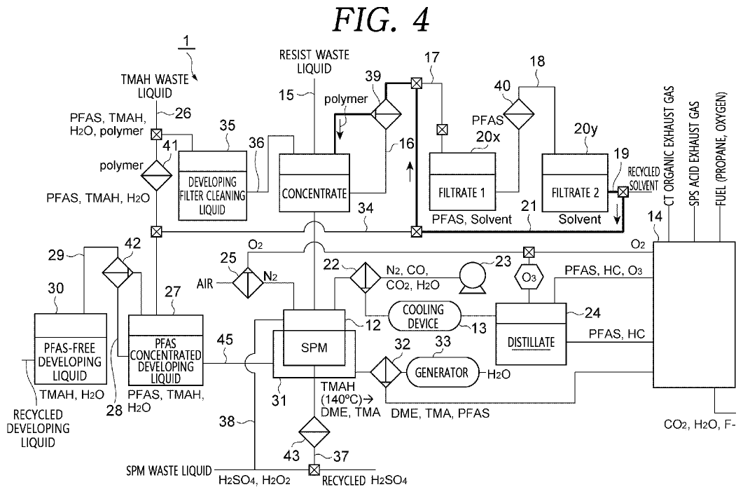

FIG. 4 is a diagram for describing cleaning of the filter 39 through a backflow of the filtrate. If the filter 39 continues to be used, it may be clogged with a polymer component or the like. As a resolution to such clogging, the filtrate flowing in the third filtrate path 19 may be introduced from an outlet side of the filter 39. That is, the bypass path 21 may be configured to connect the third filtrate path 19 to the first filtrate path 17, and by pressurizing the filtrate in the bypass path 21, the filtrate in the first filtrate path 17 may be made to flow backwards to be introduced into the circulation path 16 from the outlet side of the filter 39. Such pressurization on the liquid may be carried out by gas pressurization or a liquid feeder such as a pump. By allowing the filtrate to flow back to the filter 39, the filter 39 can be unclogged and refreshed. Further, the filtrate to be flown back may be the filtrate flowing through the second filtrate path 18.

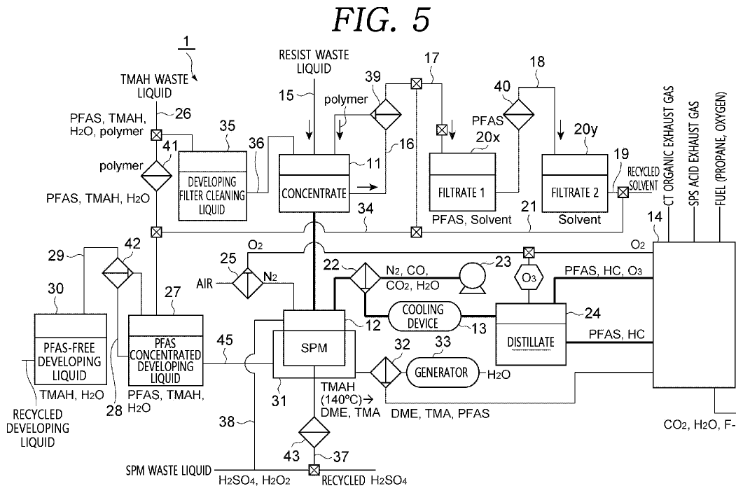

FIG. 5 is a diagram for describing gas separation. As stated above, the concentrate concentrated by the concentrating device 11 is decomposed and volatilized with the SPM waste liquid in the sulfuric acid processing tub 12. As a result, a decomposition reaction of a dehydration reaction or an oxidation reaction occurs, so that the concentrate is decomposed into a gas containing carbon monoxide, carbon dioxide, nitrogen, water vapor, a hydrocarbon-based gas, and PFAS. In this case, the gas discharged has a temperature equal to or higher than 100° C. Then, the gas volatilized in the sulfuric acid processing tub 12 is separated by the first gas filter 22. The first gas filter 22 is a filter configured to separate the gas volatilized by the sulfuric acid processing tub 12 into a PFAS-rich gas and a PFAS-removed gas. The first gas filter 22 is, for example, a pervaporation filter, and may be a ceramic filter. The first gas filter 22 receives heat generated in the sulfuric acid processing tub 12, so its temperature becomes higher than the concentrate before being decomposed. The first gas filter 22 may receive the heat generated in the sulfuric acid processing tub 12 by being disposed in the same space as the sulfuric acid processing tub 12 or by being connected to the sulfuric acid processing tub 12 by a conductive member such as a metal. In addition, the PFAS-rich gas in the present exemplary embodiment refers to a gas having a higher concentration of PFAS than a gas before being influenced by a preset action. In the above description based on FIG. 5, the separation by the first gas filter 22 corresponds to the preset action. Further, in the present exemplary embodiment, the preset action is not limited to the separation by the first gas filter 22. That is, when the PFAS-rich gas is generated, the action causing the generation of the PFAS-rich gas may be regarded as the preset action.

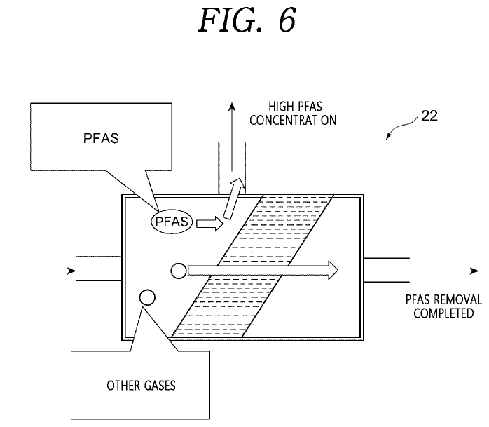

FIG. 6 is a diagram for describing a function of the first gas filter 22 when a pervaporation filter is used as the first gas filter 22. As depicted in FIG. 6, the first gas filter 22, which is the pervaporation filter, is a filter configured to separate gases by using a difference in momentum due to a difference in a molecular weight. That is, by decompressing a downstream side, the first gas filter 22 allows a gas (nitrogen, carbon monoxide, carbon dioxide, water vapor, etc.) having a relatively low molecular weight to pass therethrough (to flow to the downstream side) while not allowing a gas (PFAS, hydrocarbons) having a relatively high molecular weight to pass therethrough. As a result, the PFAS-rich gas and the PFAS-removed gas can be roughly separated.

Referring back to FIG. 5, the vacuum pump 23 is a pump configured to decompress the downstream side of the first gas filter 22 to achieve the above-described separation of the gases by the first gas filter 22. The cooling device 13 liquefies and collects the PFAS-containing gas. The collected liquid and gas are stored in the distiller 24. The liquid PFAS and hydrocarbon and the gaseous PFAS and hydrocarbon (and ozone to be described later) are introduced from the distiller 24 into the detoxifying device 14.

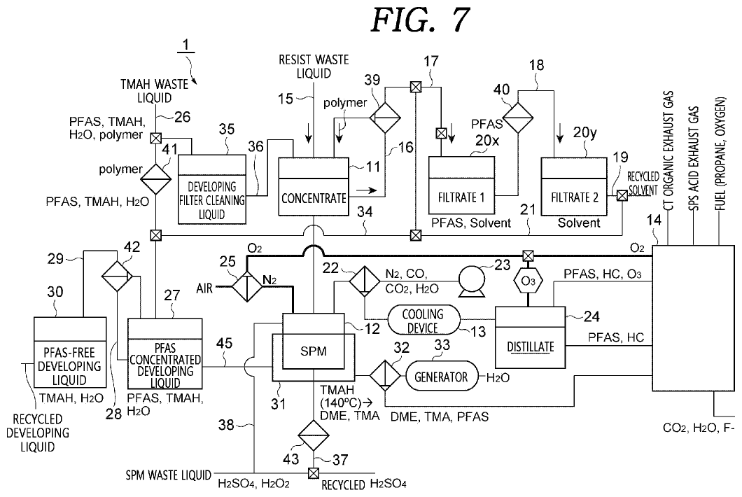

FIG. 7 is a diagram for describing separation of exterior air that has been taken in. As shown in FIG. 7, in the PFAS detoxification system 1, the exterior air is taken in, and the introduced exterior air is separated into nitrogen and oxygen by the second gas filter 25. That is, the second gas filter 25 separates the exterior air into a first separation gas (herein simply referred to as nitrogen) having a higher nitrogen concentration than air and a second separation gas (herein simply referred to as oxygen) having a higher oxygen concentration than air. Then, the second gas filter 25 supplies the nitrogen to the sulfuric acid processing tub 12. As a result, ignition in the sulfuric acid processing tub 12 is suppressed. Also, the second gas filter 25 supplies the oxygen to the detoxifying device 14. Accordingly, combustion in the detoxifying device 14 can be promoted. Additionally, ozone generated from the aforementioned oxygen may be supplied to the detoxifying device 14. This ozone may be introduced into the detoxifying device 14 via the distiller 24, or may be directly introduced into the detoxifying device 14. The ozone may be generated from the oxygen by, for example, UV radiation or electric discharge.

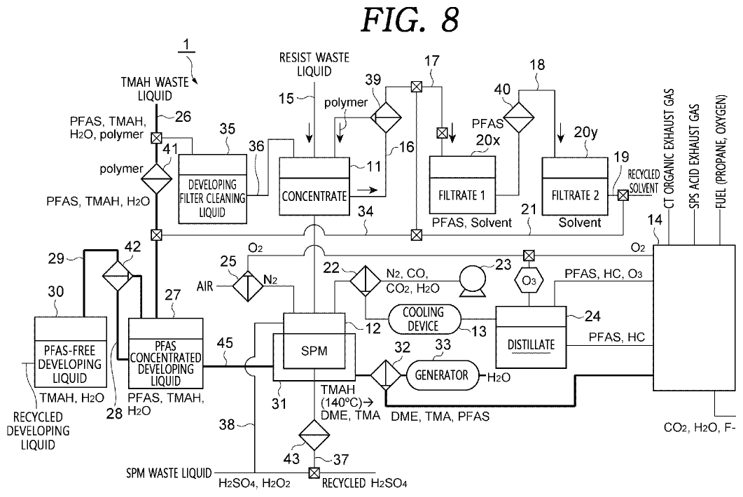

FIG. 8 is a diagram for describing concentration and decomposition of a positive developing liquid. As illustrated in FIG. 8, in the PFAS detoxification system 1, the TMAH waste liquid, which is a positive developing liquid, is introduced from the lithography apparatus 111, for example. In the PFAS detoxification system 1, the TMAH waste liquid discharged from the lithography apparatus 111 of the semiconductor manufacturing apparatus 100 is concentrated in the concentrating device 27. Further, a first concentrate, which is a concentrate of the positive developing liquid concentrated by the concentrating device 27, is decomposed and volatilized in the developing liquid processing tub 31.

The waste liquid supply path 26 is a supply path through which the TMAH waste liquid introduced from the lithography apparatus 111 is supplied to the concentrating device 27. The waste liquid supply path 26 and the waste liquid supply path 15 which supplies the resist waste liquid to the concentrating device 11 are disposed separately from each other. The waste liquid supply path 26 is provided with a filter 41 that excludes a polymer. The circulation path 28 is connected to the concentrating device 27, and is provided with a filter 42 configured to increase the concentration of the PFAS. The developing liquid (PFAS-free developing liquid) that has passed through the filter 42 flows through the developing liquid path 29 and is stored in the recycled developing liquid storage 30. This developing liquid can be used as a recycled developing liquid.

The concentrate (the developing liquid with a high concentration of the PFAS) concentrated in the concentrating device 27 is supplied to the developing liquid processing tub 31 through a concentrate path 45. The developing liquid processing tub 31 is disposed in contact with the aforementioned sulfuric acid processing tub 12 (a decomposition processor configured to decompose a second concentrate having a higher resist concentration than the first concentrate, which is the concentrate of the positive developing liquid). Specifically, the developing liquid processing tub 31 is disposed to surround the sulfuric acid processing tub 12 from below. With this configuration, the developing liquid processing tub 31 can receive the heat from the sulfuric acid processing tub 12 and is capable of decomposing and volatilizing the first concentrate by the received heat. Further, the way to decompose the first concentrate is not limited to the one using the heat, and the first concentrate may be decomposed by being exposed to microorganisms, for example. In addition, the first concentrate may be used as a solvent for cooling the SPM in the sulfuric acid processing tub 12.

The TMAH decomposed by the heat (for example, heat of about 140° C.) in the developing liquid processing tub 31 is decomposed into trimethyl amine and dimethyl ether. These gases can be used as fuel in the detoxifying device 14. The PFAS is not decomposed even by the heat, and is discharged as a gas and burned in the detoxifying device 14. The gas discharged from the developing liquid processing tub 31 includes nitrogen, water vapor, hydrocarbons, trimethyl amine, dimethyl ether, PFAS, and the like. By decompressing the downstream side, the third gas filter 32 allows a gas (nitrogen, water vapor, etc.) having a relatively low molecular weight to pass therethrough (to flow to the downstream side) while not allowing a gas (trimethyl amine, dimethyl ether, PFAS, hydrocarbon, etc.) having a relatively high molecular weight to pass therethrough. As a result, the PFAS-rich gas and the PFAS-removed gas can be roughly separated. The nitrogen and the water vapor are discharged to the outside of the system. Furthermore, by returning the discharged water vapor to water in the generator 33, power generation can be carried out by using a pressure difference. The gas containing the PFAS and the like sent to the detoxifying device 14 may be compressed, and then, sent to the detoxifying device 14.

The detoxifying device 14 may be equipped with a combustion chamber configured to mix and burn therein the gas from the first concentrate volatilized by the developing liquid processing tub 31 and the gas from the second concentrate volatilized from the sulfuric acid processing tub 12.

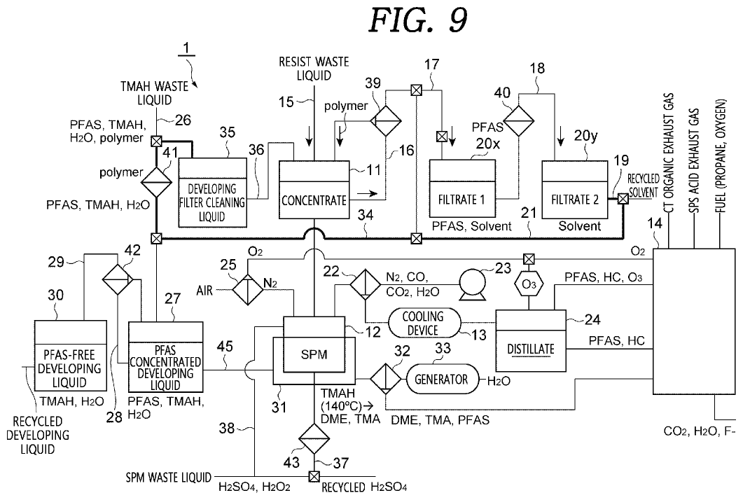

FIG. 9 is a diagram for describing cleaning of the filter 41 through a backflow of the filtrate. If the filter 41 continues to be used, it may be clogged with a polymer component or the like. As a resolution to such clogging, the filtrate flowing in the third filtrate path 19 may be introduced from an outlet side of the filter 41. That is, there is provided the bypass path 34 connected to the bypass path 21, which is connected to the third filtrate path 19, and also connected to the downstream side of the filter 41 in the waste liquid supply path 26. By pressurizing the filtrate in the bypass path 34, the filtrate in the waste liquid supply path 26 may be made to flow backwards to be introduced into the filter 41 from the outlet side thereof. Such pressurization on the liquid may be carried out by gas pressurization or a liquid feeder such as a pump. By allowing the filtrate to flow back to the filter 41, the filter 41 can be unclogged and refreshed. Furthermore, the filtrate to be flown back may be the filtrate flowing through the second filtrate path 18. Since removal of the polymer cannot be performed by the filter 41 while such filter cleaning is being performed, a plurality of filters 41 may be provided in parallel.

In the state that the filtrate is introduced from the outlet side of the filter 41, the backflow liquid flown out from an inlet side of the filter 41 is stored in the backflow liquid storage 35. The backflow liquid storage 35 is connected to the concentrating device 11 through the recovery path 36. The recovery path 36 is a path through which the backflow liquid is sent from the backflow liquid storage 35 to the concentrating device 11. Due to the presence of the recovery path 36, the liquid flown backwards for the purpose of unclogging the filter 41 can be recovered from the backflow liquid storage 35 into the concentrating device 11.

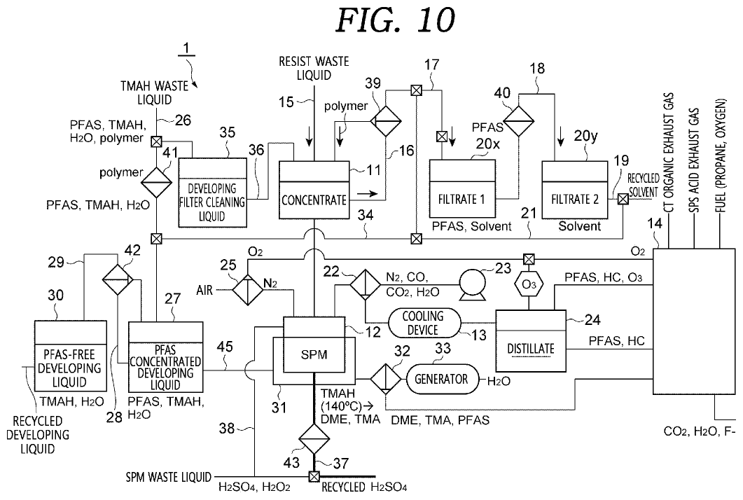

FIG. 10 is a diagram for describing discharge of the SPM waste liquid. When the reaction between the resist concentrate and the SPM waste liquid proceeds in the sulfuric acid processing tub 12, the hydrogen peroxide in the SPM is deactivated, and a reaction capacity is significantly reduced. At this time, the SPM becomes a concentrated sulfuric acid state, causing a dehydration reaction. As carbonization of an organic matter progresses, the liquid is discolored to yellow or brown. For this reason, the SPM waste liquid is discharged from the discharge path 37 at a timepoint when the liquid turns yellow. At this time, filtering of a carbide is performed by a filter 43 provided in the discharge path 37. The discharged SPM waste liquid can be used as recycled sulfuric acid because it is free of hydrogen peroxide and is given increased purity of sulfuric acid through the filtering by the filter 43.

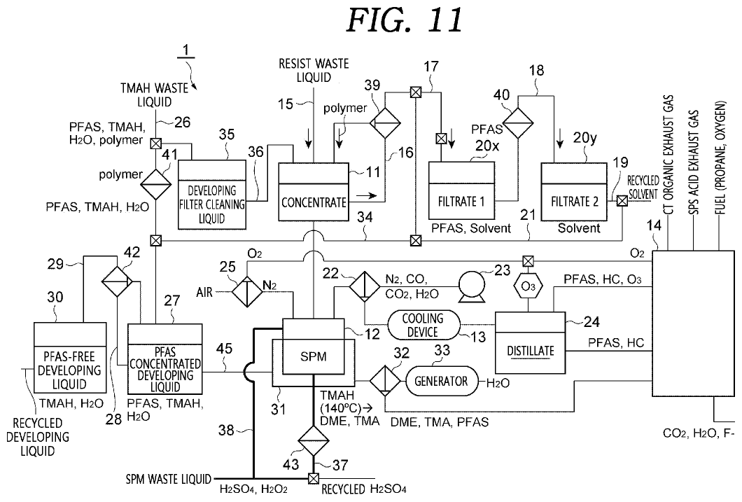

FIG. 11 is a diagram for describing cleaning of the filter 43 by the SPM waste liquid. When a new SPM waste liquid is supplied to the sulfuric acid processing tub 12, the filter 43 trapping the carbide can be cleaned by allowing some of this new SPM waste liquid to be introduced from an outlet side of the filter 43. That is, in the SPM supply path 38 for supplying the new SPM waste liquid to the sulfuric acid processing tub 12, by allowing the SPM waste liquid to flow to a portion of the SPM supply path 38 connected to an outlet of the filter 43, the SPM waste liquid may be made to react with the carbide trapped in the filter 43. As a result, the carbide trapped in the filter 43 is exhausted as carbon dioxide, and the filter 43 is cleaned.

Now, effects of the PFAS detoxification system 1 according to the present exemplary embodiment will be explained.

The PFAS detoxification system 1 according to the present exemplary embodiment includes the concentrating device 11 configured to concentrate a resist waste liquid containing PFAS discharged from the lithography apparatus 111 of the semiconductor manufacturing apparatus 100. Further, the PFAS detoxification system 1 includes the sulfuric acid processing tub 12 configured to decompose and volatilize the concentrate concentrated by the concentrating device 11. In the PFAS detoxification system 1 according to the present exemplary embodiment, after a waste liquid containing PFAS is concentrated, the concentrate is decomposed and volatilized. As a result, a polymer, a solvent, and the like become to have a low molecular weight through a decomposition reaction of a dehydration reaction, and the PFAS is volatilized. According to this PFAS detoxification system 1, a detoxification processing for the PFAS can be performed smoothly.

The sulfuric acid processing tub 12 may decompose and volatilize the concentrate with a liquid containing hot concentrated sulfuric acid. In this way, as the concentrate is mixed with the liquid containing the hot concentrated sulfuric acid, the polymer, the solvent, and the like become to have a low molecular weight through a decomposition reaction of a dehydration reaction, and the PFAS is volatilized. By degassing the mixed liquid through an organic substance reaction, the liquid is less likely to foam in a subsequent processing, which makes the subsequent processing to be easily performed.

The PFAS detoxification system 1 is further equipped with the circulation path 16 connected to the concentrating device 11 and provided with the filter 39; and the first filtrate path 17 through which a filtrate of the concentrate that has passed through the filter flows. Further, the PFAS detoxification system 1 is also equipped with the first storage 20x connected to the first filtrate path 17 and configured to store the filtrate therein. With this configuration, the waste liquid can be appropriately concentrated by using the filter 39, and the filtrate that has passed through the filter 39 can be stored to be used as a recycled solvent, for example.

The PFAS detoxification system 1 further includes the third filtrate path 19 downstream from the second storage 20y; and the bypass path 21 connecting the third filtrate path 19 to the first filtrate path 17. In the PFAS detoxification system 1, the liquid in the bypass path 21 is pressurized, causing the liquid to flow backwards in the first filtrate path 17 to be introduced into the circulation path 16 from the outlet side of the filter 39. In this way, by introducing the filtrate into the filter 39 from the outlet side thereof through the bypass path 21, the clogging of the filter 39 can be resolved, and the filter 39 can be properly cleaned.

The PFAS detoxification system 1 further includes the second filtrate path 18 provided with the filter 40, and the second filtrate path 18 connects the first storage 20x and the second storage 20y. In this way, by adopting the configuration in which the two storages are provided as filtrate storages and the filter 40 is provided between them, the filtrate with a reduced concentration of the PFAS can be appropriately extracted and stored.

The PFAS detoxification system 1 may be further equipped with the first gas filter 22 configured to separate the gas volatilized by the sulfuric acid processing tub 12 into a PFAS-rich gas and a PFAS-removed gas. By providing this first gas filter 22, the PFAS-rich gas and the PFAS-free gas can be appropriately separated.

The first gas filter 22 may receive the heat generated in the sulfuric acid processing tub 12 and thus have a temperature higher than that of the concentrate. In this way, as the temperature of the first gas filter 22 becomes high, the PFAS, which is a sorting target, is difficult to pass through the first gas filter 22 as compared to other gases. Thus, it is possible to appropriately perform the gas separation by utilizing a difference in flow velocity caused by the temperature rise.

The PFAS detoxification system 1 is also equipped with the second gas filter 25 configured to take in the exterior air and separate the exterior air into a first separation gas having a higher nitrogen concentration than air and a second separation gas having a higher oxygen concentration than air. The second gas filter 25 may supply the first separation gas to the sulfuric acid processing tub 12. In this way, by supplying the gas with the high nitrogen concentration to the sulfuric acid processing tub 12, the ignition in the sulfuric acid processing tub 12 can be suppressed.

The PFAS detoxification system 1 further includes the detoxifying device 14 configured to burn and detoxify the PFAS contained in the gas volatilized by the sulfuric acid processing tub 12, and the second gas filter 25 may supply the second separation gas to the detoxifying device 14. In this way, by supplying the gas with the high oxygen concentration to the detoxifying device 14, the combustion in the detoxifying device 14 can be accelerated.

The PFAS detoxification system 1 may also be equipped with the concentrating device 27 configured to concentrate a waste liquid containing a positive developing liquid discharged from the lithography apparatus 111 of the semiconductor manufacturing apparatus 100, and the developing liquid processing tub 31 configured to decompose and volatilize a first concentrate concentrated by the concentrating device 27. In the PFAS detoxification system 1 according to the present exemplary embodiment, after the waste liquid containing the positive developing liquid, which is a waste liquid containing PFAS, is concentrated, the concentrate is decomposed and volatilized. As a result, the polymer, the solvent, and the like become to have a low molecular weight through a decomposition reaction of a dehydration reaction, and the PFAS is volatilized. According to this PFAS detoxification system 1, the detoxification processing for the PFAS can be performed smoothly.

The PFAS detoxification system 1 includes the waste liquid supply path 26 through which the waste liquid containing the positive developing liquid is supplied to the concentrating device 27; and the waste liquid supply path 15 through which the waste liquid having a higher resist concentration than the waste liquid containing the positive developing liquid is supplied to the sulfuric acid processing tub 12 which is a decomposition processor for the corresponding waste liquid. Further, the waste liquid supply path 26 and the waste liquid supply path 15 are provided separately from each other. In this way, by adopting the configuration in which a supply path (waste liquid supply path 26) for the waste liquid containing the positive developing liquid and a supply path (waste liquid supply path 15) for the waste liquid having the high resist concentration are provided separately from each other, generation of an extra salt due to an acid-alkali reaction, or the like can be suppressed.

The developing liquid processing tub 31 may be configured to decompose and volatilize the first concentrate by heat. In this way, by decomposing the first concentrate with the heat, the first concentrate can be appropriately decomposed.

The developing liquid processing tub 31 may be disposed in contact with the sulfuric acid processing tub 12, which is a decomposition processor for a second concentrate having a higher resist concentration than the first concentrate. With this configuration, the first concentrate can be appropriately separated by using the heat of the reaction in the sulfuric acid processing tub 12, which is the decomposition processor for the second concentrate. In addition, since the developing liquid processing tub 31 is disposed in contact with the sulfuric acid processing tub 12, a container of the sulfuric acid processing tub 12 (and the SPM waste liquid as well) can be cooled.

The PFAS detoxification system 1 further includes the detoxifying device 14 configured to burn and detoxify PFAS. The detoxifying device 14 has a combustion chamber in which the gas from the first concentrate volatilized by the developing liquid processing tub 31 and the gas from the second concentrate volatilized by the sulfuric acid processing tub 12 are mixed and burned. In this way, the gas from the first concentrate decomposed and volatilized by the developing liquid processing tub 31 and the gas from the second concentrate decomposed and volatilized by the sulfuric acid processing tub 12 are used for the combustion in the combustion chamber. Thus, the fuel introduced into the detoxifying device 14 can be reduced, total CO₂ discharge can be suppressed, and scale-up of incineration facilities can be suppressed.

The PFAS detoxification system 1 may pressurize the filtrate in the bypass path 34 to cause the corresponding liquid to flow backwards in the waste liquid supply path 26 to be introduced into the filter 41 from the outlet side thereof. In this way, by introducing the filtrate from the outlet side of the filter 41 through the bypass path 34, the clogging of the filter 41 can be resolved, and the filter 41 can be properly cleaned.

The PFAS detoxification system 1 is equipped with the backflow liquid storage 35 configured to store therein a backflow liquid flowing out from the inlet side of the filter 41 in the state that the filtrate is introduced from the outlet side of the filter 41. Furthermore, the PFAS detoxification system 1 may be further equipped with the recovery path 36 that connects the backflow liquid storage 35 to the concentrating device 11 to send the backflow liquid from the backflow liquid storage 35 to the concentrating device 11. With this configuration, the liquid flown backwards for the purpose of cleaning the filter 41 can be appropriately recovered.

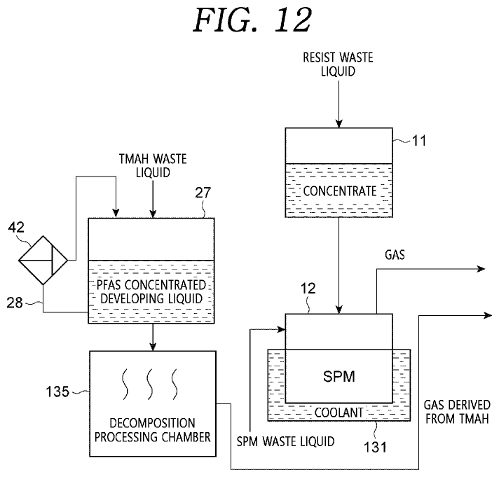

So far, the exemplary embodiment has been described. However, the present disclosure is not limited to the above described exemplary embodiment. For example, in the above description, although the chemical liquid processor for the waste liquid containing the positive developing liquid is disposed in contact with the sulfuric acid processing tub 12, which is a chemical liquid processor for the resist waste liquid, the chemical liquid processor for the waste liquid containing the positive developing liquid is not limited thereto. By way of example, as shown in FIG. 12, a decomposition processing chamber 135 as a chemical liquid processor for the waste liquid containing the positive developing liquid may be provided away from the sulfuric acid processing tub 12. In this case, the sulfuric acid processing tub 12 may be cooled by a coolant tank 131 containing a coolant.

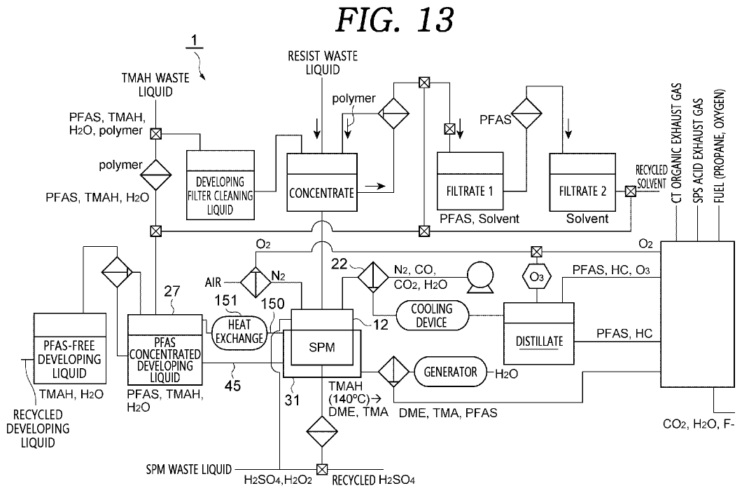

In addition, as illustrated in FIG. 13, a flow path 150 connecting the concentrating device 27 and the developing liquid processing tub 31 may be provided, and this flow path 150 may be provided with a heat exchanger 151. In this case, the first concentrate in the developing liquid processing tub 31 can be returned to the concentrating device 27 via the flow path 150.

Finally, various exemplary embodiments included in the present disclosure are described in [E1] to [E23] below.

[E1] A processing system including a concentrator configured to concentrate a waste liquid containing an organic fluorine compound, discharged from a semiconductor manufacturing apparatus; and a chemical liquid processor configured to decompose and volatilize a concentrate concentrated by the concentrator.

[E2] The processing system described in [E1], wherein the chemical liquid processor decomposes and volatilizes the concentrate with a liquid containing hot concentrated sulfuric acid.

[E3] The processing system described in [E1] or [E2], further including: a first path, serving as a circulation path connected to the concentrator, provided with a first filter in a portion thereof; a second path through which a filtrate of the concentrate passing through the first filter flows; and a filtrate storage connected to the second path, and configured to store the filtrate therein.

[E4] The processing system described in [E3], further including: a third path disposed downstream of the filtrate storage; a bypass path connecting the third path and the second path; and a liquid feeder configured to pressurize a liquid within the bypass path to cause the liquid to flow backwards in the second path to be introduced into the first path from an outlet side of the first filter.

[E5] The processing system described in [E4], further including: a fourth path provided with a second filter, wherein the filtrate storage includes a first storage connected to the second path, and a second storage connected to the third path, and the fourth path connects the first storage and the second storage.

[E6] The processing system described in any one of [E1] to [E5], further including: a first gas filter configured to separate a gas volatilized by the chemical liquid processor into an organic fluorine compound-rich gas and an organic fluorine compound-removed gas.

[E7] The processing system described in [E6], wherein the first gas filter is configured to receive heat generated in the chemical liquid processor to have a temperature higher than the concentrate.

[E8] The processing system described in any one of [E1] to [E7], further including: a second gas filter configured to take in exterior air and configured to separate the exterior air into a first separation gas having a higher nitrogen concentration than air and a second separation gas having a higher oxygen concentration than the air, wherein the second gas filter is configured to supply the first separation gas to the chemical liquid processor.

[E9] The processing system described in [E8], further including: a combustion detoxifying device configured to burn and detoxify an organic fluorine compound contained in a gas volatilized by the chemical liquid processor, wherein the second gas filter supplies the second separation gas to the combustion detoxifying device.

[E10] A processing method, including: concentrating a waste liquid containing an organic fluorine compound, discharged from a semiconductor manufacturing apparatus; and decomposing and volatilizing a concentrate concentrated in the concentrating of the waste liquid.

[E11] The processing method described in [E10], further including: cleaning a first filter used in the concentrating of the waste liquid by introducing a filtrate of the concentrate passing through the first filter from an outlet side of the first filter.

[E12] The processing method described in [E10] or [E11], further including: separating a gas volatilized in the decomposing and volatilizing of the concentrate into an organic fluorine compound-rich gas and an organic fluorine compound-removed gas through a first gas filter.

[E13] The processing method described in any one of [E10] to [E12], further including: separating, through a second gas filter, exterior air into a first separation gas having a higher nitrogen concentration than air and a second separation gas having a higher oxygen concentration than the air, and supplying the first separation gas to a processor configured to perform the decomposing and volatilizing of the concentrate.

[E14] A processing system, including: a developing liquid concentrator configured to concentrate a waste liquid containing a positive developing liquid, discharged from a semiconductor manufacturing apparatus; and a chemical liquid processor configured to decompose and volatilize a first concentrate concentrated by the developing liquid concentrator.

[E15] The processing system described in [E14], further including: a first supply path through which the waste liquid containing the positive developing liquid is supplied to the developing liquid concentrator, wherein the first supply path is provided separately from a second supply path through which a waste liquid having a higher resist concentration than the waste liquid containing the positive developing liquid is supplied to a decomposition processor corresponding to the waste liquid having the higher resist concentration.

[E16] The processing system described in [E14] or [E15], wherein the chemical liquid processor decomposes and volatilizes the first concentrate by heat.

[E17] The processing system described in any one of [E14] to [E16], wherein the chemical liquid processor is disposed in contact with a decomposition processor of a second concentrate having a higher resist concentration than the first concentrate.

[E18] The processing system described in [E17], further including: a combustion detoxifying device configured to detoxify an organic fluorine compound by combustion, wherein the combustion detoxifying device includes a combustion chamber in which a gas from the first concentrate volatilized by the chemical liquid processor and a gas from the second concentrate volatilized by the decomposition processor are mixed and burned.

[E19] The processing system described in any one of [E14] to [E18], including: a first supply path, serving as a supply path through which the waste liquid containing the positive developing liquid is supplied to the developing liquid concentrator, provided with, in a portion thereof, a filter for the waste liquid containing the positive developing liquid; a filtrate path through which a filtrate passing through a filter configured to concentrate a waste liquid having a higher resist concentration than the waste liquid containing the positive developing liquid flows; a bypass path connecting the filtrate path and the first supply path; and a liquid feeder configured to pressurize a filtrate within the bypass path to cause the filtrate to flow backwards in the first supply path and the filtrate to be introduced into the filter for the waste liquid containing the positive developing liquid from an outlet side thereof.

[E20] The processing system described in [E19], further including: a waste liquid storage configured to store therein the waste liquid having the higher resist concentration than the waste liquid containing the positive developing liquid; a backflow liquid storage configured to store therein a backflow liquid flown out from an inlet side of the filter for the waste liquid containing the positive developing liquid in a state that the filtrate is introduced from the outlet side of the filter; and a recovery path connecting the backflow liquid storage and the waste liquid storage to send the backflow liquid from the backflow liquid storage to the waste liquid storage.

[E21] A processing method, including: concentrating a waste liquid containing a positive developing liquid, discharged from a semiconductor manufacturing apparatus; and decomposing and volatilizing a first concentrate concentrated in the concentrating of the waste liquid.

[E22] The processing method described in [E21], wherein in the decomposing and volatilizing of the first concentrate, the first concentrate is decomposed and volatilized by using heat generated from a decomposition reaction of a second concentrate having a higher resist concentration than the first concentrate.

[E23] The processing method described in [E21] or [E22], further including: cleaning a filter used in the concentrating of the waste liquid by introducing, from an outlet side of the filter, a filtrate passing through another filter configured to concentrate a waste liquid having a higher resist concentration than the waste liquid containing the positive developing liquid.

According to the exemplary embodiment, it is possible to perform the detoxification processing for the organic fluorine compound.

It should be noted that the above-described exemplary embodiments are illustrative in all aspects and are not anyway limiting. In fact, the above-described exemplary embodiments can be embodied in various forms. Further, the above-described exemplary embodiments may be omitted, replaced and modified in various ways without departing from the scope and the spirit of claims.

We claim:

1. A processing system, comprising:
a developing liquid concentrator configured to concentrate a waste liquid containing a positive developing liquid, discharged from a semiconductor manufacturing apparatus; and
a chemical liquid processor configured to decompose and volatilize a first concentrate concentrated by the developing liquid concentrator.

2. The processing system of claim 1, further comprising:
a first supply path through which the waste liquid containing the positive developing liquid is supplied to the developing liquid concentrator,
wherein the first supply path is provided separately from a second supply path through which a waste liquid having a higher resist concentration than the waste liquid containing the positive developing liquid is supplied to a decomposition processor corresponding to the waste liquid having the higher resist concentration.

3. The processing system of claim 1,
wherein the chemical liquid processor decomposes and volatilizes the first concentrate by heat.

4. The processing system of claim 3,
wherein the chemical liquid processor is disposed in contact with a decomposition processor of a second concentrate having a higher resist concentration than the first concentrate.

5. The processing system of claim 4, further comprising:
a combustion detoxifying device configured to detoxify an organic fluorine compound by combustion,
wherein the combustion detoxifying device comprises a combustion chamber in which a gas from the first concentrate volatilized by the chemical liquid processor and a gas from the second concentrate volatilized by the decomposition processor are mixed and burned.

6. The processing system of claim 1, comprising:
a first supply path, serving as a supply path through which the waste liquid containing the positive developing liquid is supplied to the developing liquid concentrator, provided with, in a portion thereof, a filter for the waste liquid containing the positive developing liquid;
a filtrate path through which a filtrate passing through a filter configured to concentrate a waste liquid having a higher resist concentration than the waste liquid containing the positive developing liquid flows;
a bypass path connecting the filtrate path and the first supply path; and
a liquid feeder configured to pressurize a filtrate within the bypass path to cause the filtrate to flow backwards in the first supply path and the filtrate to be introduced into the filter for the waste liquid containing the positive developing liquid from an outlet side thereof.

7. The processing system of claim 6, further comprising:
a waste liquid storage configured to store therein the waste liquid having the higher resist concentration than the waste liquid containing the positive developing liquid;
a backflow liquid storage configured to store therein a backflow liquid flown out from an inlet side of the filter for the waste liquid containing the positive developing liquid in a state that the filtrate is introduced from the outlet side of the filter; and
a recovery path connecting the backflow liquid storage and the waste liquid storage to send the backflow liquid from the backflow liquid storage to the waste liquid storage.

8. A processing method, comprising:
concentrating a waste liquid containing a positive developing liquid, discharged from a semiconductor manufacturing apparatus; and
decomposing and volatilizing a first concentrate concentrated in the concentrating of the waste liquid.

9. The processing method of claim 8,
wherein in the decomposing and volatilizing of the first concentrate, the first concentrate is decomposed and volatilized by using heat generated from a decomposition reaction of a second concentrate having a higher resist concentration than the first concentrate.

10. The processing method of claim 8, further comprising:
cleaning a filter used in the concentrating of the waste liquid by introducing, from an outlet side of the filter, a filtrate passing through another filter configured to concentrate a waste liquid having a higher resist concentration than the waste liquid containing the positive developing liquid.
